(19) United States
(12) Patent Application Publication
(10) Pub. No.: US 2006/0076123 A1
(43) Pub. Date: Apr. 13, 2006

(54) Tube type heat exchanger with motor or generator housing

(76) Inventor: James Larry Jones, Denver, CO (US)

Correspondence Address: CARLSON, GASKEY & OLDS, P.C., 400 WEST MAPLE ROAD, SUITE 350, BIRMINGHAM, MI, 48009, US

(21) Appl. No.: 11/290,251

(22) Filed: Nov. 30, 2005

Related U.S. Application Data
(62) Division of application No. 09/862,910, filed on May 22, 2001, now abandoned.

(51) Int. Cl. H05K 7/20

(52) U.S. Cl. 165/80.4; 165/156; 361/699

(57) ABSTRACT

A cooling assembly is provided for an electromechanical device, such as an electromagnetic or generator, including a housing having a wall portion. A magnetic field member is disposed within the housing and is arranged adjacent to the wall portion. A shaft having windings is located within the magnetic field member with an electric current flowing through the windings, which coacts with the magnetic field member. The magnetic field member and the windings produces an undesirable level of heat. The present invention incorporates a helical cooling coil defining a fluid conduit arranged adjacent to the magnetic field member for removing heat from the electromechanical device.

### BACKGROUND OF THE INVENTION

This invention relates to a cooling device for an electromechanical device, and more particularly, the invention relates to a heat exchanger for an electric motor or generator.

Generators are utilized to convert rotary motion to electricity. Electric motors are utilized to produce rotary motion in response to electricity. Both generators and electric motors produce heat that may rise to an undesirable level. As a result, a cooling device may be required to reduce the heat generated by the electric motor or generator. A typical cooling device incorporates a fluid conduit or chamber for carrying fluid to an area near the motor or generator to absorb heat and reduce the temperature of the electrical mechanical device.

In aerospace applications, customers prefer that the cooling fluid come into contact with stainless steel only to minimize the impact of the corrosive effects of the cooling fluid. A prior art device shown in FIG. 1, depicts an electromechanical device 10 such as an electric motor or generator. The electromechanical device includes a housing 12. A cooling chamber 14 is formed by securing an external wall 13 to the housing 12. The housing 12 may be relatively thick to provide structural integrity to the device 10. The external wall 13 may be rather large to cover much of the housing 12. In conformance with customer expectations, the housing 12 and external wall 13 must be constructed from stainless steel. As a result, large portions of the electromechanical device 10 must be constructed from stainless steel thereby adding significant cost to the motor or generator. Therefore, what is needed is an improved cooling device for electric motors and generators that minimizes the use of stainless steel while still providing effective cooling.

### SUMMARY OF THE INVENTION AND ADVANTAGES

The present invention provides a cooling assembly for an electromechanical device, such as an electric motor or generator, including a housing having a wall portion. A magnetic field member is disposed within the housing and is arranged adjacent to the wall portion. A shaft having windings is located within the magnetic field member with an electric current flowing through the windings, which coacts with the magnetic field member. The magnetic field member and/or the windings produces an undesirable level of heat. The present invention incorporates a helical cooling coil defining a fluid conduit arranged adjacent to the magnetic field member for removing heat from the electromechanical device.

Accordingly, to the above invention provides an improved cooling device for electric motors and generators that minimizes the use of stainless steel while still providing effective cooling.

### BRIEF DESCRIPTION OF THE DRAWINGS

Other advantages of the present invention can be understood by reference to the following detailed description when considered in connection with the accompanying drawings wherein:

FIG. 1 is a cross-sectional view of a prior art electromechanical device such as an electric motor or generator;

FIG. 2 is a cross-sectional view of an electromechanical device incorporating the present invention;

FIG. 3A is an enlarged cross-sectional view of an alternative embodiment of the present invention; and

FIG. 3B is an enlarged cross-sectional view of yet another embodiment of the present invention.

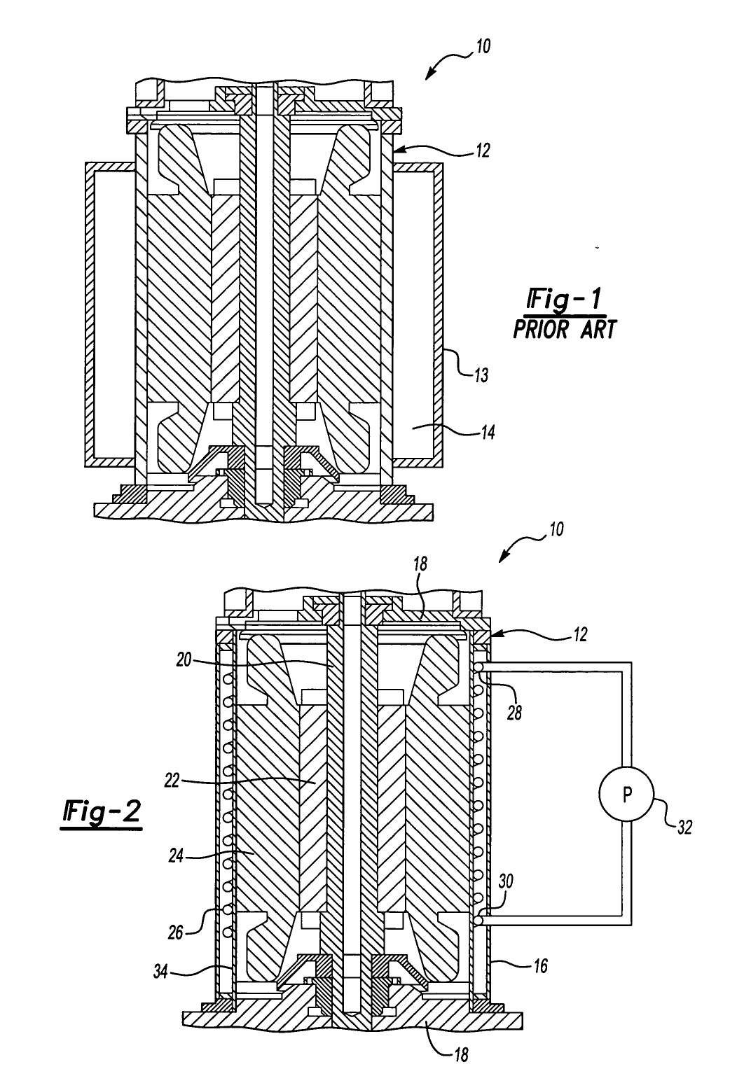

### DETAILED DESCRIPTION OF THE PREFERRED EMBODIMENT

An electromechanical assembly 10, such as an electric motor or generator, is shown in FIG. 2. The assembly 10 includes a housing 12 having a wall portion 16 and opposing end portions 18 secured to the wall portion 16. Preferably, the wall portion 16 is cylindrical in shape. A shaft 20 is supported by the end portions 18 for rotation relative to the housing 12. The shaft 20 includes wire windings 22. A magnetic field member 24 is arranged about the shaft 20 and windings 22 within the housing 12 and preferably, adjacent to the wall portions 16.

The electromechanical assembly 10 may be either an electric motor or a generator. In the case of an electric motor, the magnetic field member 24 is a stator that carries the current which produces a magnetic field. The windings 22 and shaft 20 form a rotor which rotates in response to the magnetic field produced by the stator. In the case of a generator, the shaft 20 is rotationally driven by an external drive. They windings 22 have current flowing therethrough, which produces a magnetic field that generates a current in the magnetic field member 24 thereby producing electricity.

One embodiment of the cooling device is shown in FIG. 2. The cooling device includes a tube, preferably in the shape of a helical cooling coil 26, which has an inlet 28 and an outlet 30. A pump 32 is fluidly connected to the inlet 28 and outlet 34 pumping fluid through the helical coil for absorbing heat produced by the electromechanical device 10. As shown in FIG. 2, the helical coil 26 may be secured to a thin shell 34 that is arranged between the end portions 18 and spaced from the magnetic field member 24. In conformance with industry preferences, the helical coil 26 is preferably constructed from stainless steel. However, it is to be understood that the helical coil 26 may be constructed for many other suitable material that is compatible with the cooling fluid.

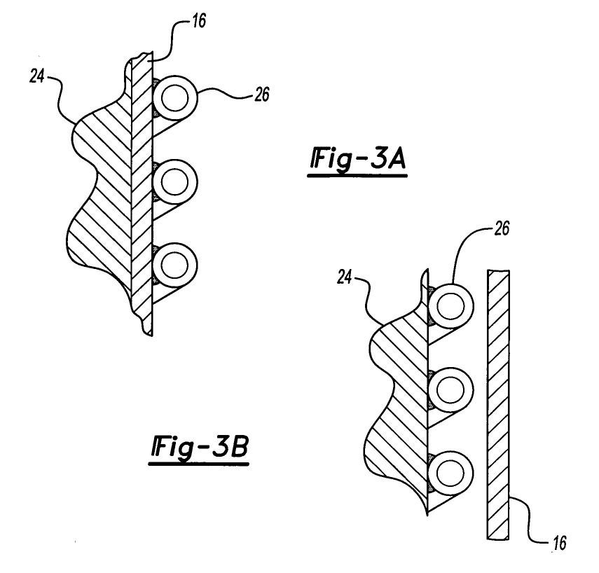

In another embodiment shown in FIG. 3A, the wall portion 16 may be arranged immediately adjacent to the magnetic field member 24. The helical coils 26 may be secured to the wall portion 16 there by eliminating the thin shell 34. In yet another embodiment shown in FIG. 3B, the helical coils 26 may be arranged immediately adjacent to the magnetic field generator 24 and in proximity to the wall portion 16. In the embodiments shown in FIGS. 2, 3A and 3B, the cooling coils 26 may be brazed to the wall portion 16, magnetic field generator 24, or thin shell 34. Of course the helical coils 26 may be supported relative to the housing 12 in any other suitable manner.

By utilizing the helical coils of the present invention, the large stainless steel housing and external wall of the prior art may be eliminated thereby reducing the overall cost of the electromechanical device.

The invention has been described in an illustrative manner, and it is to be understood that the terminology that has been used is intended to be in the nature of words of description rather than of limitation. Obviously, many modifications and variations of the present invention are possible in light of the above teachings. It is, therefore, to be understood that within the scope of the appended claims the invention may be practiced otherwise than as specifically described.

1.-6. (canceled)

7. A cooling assembly for an electromechanical device, the assembly comprising:
a housing having a wall portion;
a magnetic field member disposed within said housing and arranged adjacent said wall portion;
a shaft having windings located within said magnetic field member with an electrical current flowing through said windings coacting with said magnetic field member, wherein at least one of said magnetic field member and said windings produces heat; and
a helical cooling coil defining a fluid conduit arranged adjacent said magnetic field member for removing said heat, wherein said wall portion is disposed between said coil and said windings with said coils secured to said wall portion.

8. (canceled)

9. The assembly according to claim 7, wherein rotation of said shaft produces a current in said magnetic field generator.

10. A method of cooling an electromechanical device comprising the steps of:
a) producing heat in the electromechanical device having a temperature;
b) pumping fluid through a helical coil arranged about a portion of the electromechanical device; and
c) absorbing the heat in the fluid to reduce the temperature.

11.-12. (canceled)

13. The assembly according to claim 7, wherein said mechanical fastening element is a brazed joint connecting said coils to said wall.
